(19) United States
(12) Patent Application Publication
(10) Pub. No.: US 2024/0397749 A1
(43) Pub. Date: Nov. 28, 2024

(54) BAND-EDGE EMISSION ENHANCED ORGANIC LIGHT EMITTING DIODES WITH SIMPLIFIED STRUCTURES AND HIGH ENERGY EFFICIENCY

(71) Applicant: Red Bank Technologies LLC, Red Bank, NJ (US)

(72) Inventors: John N. MAGNO, Newtown, PA (US); Gene C. KOCH, Corvallis, OR (US)

(21) Appl. No.: 18/714,561

(22) PCT Filed: Dec. 2, 2022
(86) PCT No.: PCT/US2022/080843

§ 371 Date: May 29, 2024

Related U.S. Application Data
(60) Provisional application No. 63/285,741, filed on Dec. 3, 2021.

(51) Int. Cl. H10K 50/858; C09K 11/06; H10K 50/11; H10K 85/60

(52) U.S. Cl. CPC H10K 50/858; C09K 11/06; H10K 50/11; H10K 85/636; H10K 85/654; C09K 2211/1007; C09K 2211/1014; C09K 2211/1018; H10K 85/6572

(57) ABSTRACT

A light emitting device is described, including a single light emitting photonic crystal having a stop band and organic electroluminescent emitter material within. The device includes a reflective metal cathode. The organic electroluminescent emitter material includes an organic light emitting material localized in a layer having less than 20% of an optical thickness of the photonic crystal and has a free space emission spectrum overlapping the stop band of the photonic crystal. The photonic crystal emits light at a wavelength corresponding to an edge of the stop band, has a periodically varying refractive index, and includes alternating layers of high index and low index of refraction materials. One of the layers of low index of refraction materials includes a zone containing the organic electroluminescent emitter material with additional sub-layers each having a low index of refraction, and with the organic electroluminescent emitter material adjacent to the reflective metal cathode.

This application claims benefit of co-pending U.S. provisional patent application Ser. No. 63/285,741 filed Dec. 3, 2021. The aforementioned related patent application is herein incorporated by reference in its entirety.

### BACKGROUND

The following description relates to an improved light emitting device and methods of manufacturing the same.

Organic light-emitting diodes (“OLEDs”) are optoelectronic devices made by placing a layer of organic material between two electrodes, which when a voltage potential is applied to the electrodes and current is injected through the organic material, visible light is emitted from the organic material or emissive material. Due to the high power efficiency, low cost of manufacture, lightweight and durability, OLEDs are often used to create visual displays for portable and non-portable devices as well as consumer lighting.

OLEDs are rapidly replacing liquid crystal display (“LCD”) devices in the market for lighting and display devices. This is driven by advantages in viewing experience, size, weight, and simplicity. U.S. Pat. No. 11,139,456 generically describes light emitting photonic crystal devices and a number of versions of these devices are described in that patent and subsequent continuation application US2020/295,305, each of which is herein incorporated by reference. These devices are collectively referred to as band-edge emission enhanced organic light emitting diodes (BE-OLEDs). Generally, BE-OLED architectures are useful in both non-laser and laser applications. Since light is emitted by a BE-OLED through emission stimulated by light retained in the photonic crystal structure, light emitted by BE-OLEDs is predominantly collimated and emitted normal or near normal to the surface or the device.

A great advantage of BE-OLEDs is that the energy efficiency of the devices is greatly enhanced vis-a-vis conventional OLEDs. The majority or light produced in conventional OLEDs never emerges from these devices because it is emitted at angles far enough from the normal to the device surface that it is trapped in the device by internal reflections. Since essentially all the light emitted by BE-OLEDs is emitted at near normal angles, nearly all the light that is produced within the devices escapes. This can result in a three-fold increase in energy efficiency.

A typical version of a BE-OLED structure 100 as previously described in U.S. Pat. No. 11,139,456 is shown in FIG. 1. The device comprises three sub-structures, a first portion of the photonic crystal structure 117, a central low refractive index zone 112, and a second portion of the photonic crystal structure 104. These structures are successively built up on substrate 118 by vacuum deposition. The references to “a portion” are meant as convention to ease the description of the components of device 100 which is formed to be a single unitary one-dimensional photonic crystal. Evidence that the device 100 acts as such is that a “stop band” (or band gap) is formed in the device structure. That is to say that within the structure no propagation modes of light transmission in the direction perpendicular to the layers in device 100 are allowed over a band of wavelengths within the electromagnetic spectrum. This band of wavelengths is known as the “stop band”. It is a property of photonic crystals that a light emitting material located within the photonic crystal will emit light at higher levels of radiance than may be expected in a vacuum at wavelengths at the edges of the stop band. A further property of photonic crystals is that a large portion of the light emitted by this light emitting material will be retained for a time in the photonic crystal.

Aside from the three sub-structures listed above device 100 also comprises a transparent anode layer 113, a thin first cathode layer 106 composed of low work function metal and a second transparent cathode layer 105. Transparent anode 113 and transparent cathode layer 105 are both formed from materials with higher refractive indices than adjacent low refractive index layers 114 and 102 respectively. Transparent electrode layers 113 and 105 each have optical thicknesses equal to one-quarter of the central wavelength λ of the stop-band of the photonic crystal device 100.

The first portion 117 of the photonic crystal structure 119 comprises five layer pairs 116. Each of the layer pairs comprises a layer 115 of transparent high refractive index material overlaid by a layer 114 of low refractive index material. Each of the layers comprised by layer pairs 116 have an optical thickness equal to one-quarter of the central wavelength of the stop band of the photonic crystal 119. The optical thicknesses of the layers are equal to the physical thickness of the layers times the refractive index of the layer. Similarly, the second portion of the photonic crystal structure 104 comprises five layer pairs 103. Each of the layer pairs 103 comprises a layer 102 of transparent low refractive index material overlaid by a layer 101 of high refractive index material. Each of the layers comprised by layer pairs 103 have an optical thickness equal to one-quarter of the central wavelength of the stop-band of the photonic crystal sub-structure 104.

The central low refractive index zone 112 comprises a hole injection layer 111, a hole transporting layer 110, an emitter layer 109, an electron transporting layer 108, and an electron injection layer 107. All of the layers contained in central low refractive index zone 112 have refractive indices lower than the materials in electrodes 105 and 113. The combined optical thicknesses of the layers in zone 112 (plus the optical thickness of metal layer 106 that likely has a very low refractive index, but also negligible thickness) is equal to one-quarter of the central wavelength of the stop-band of the photonic crystal 119. It can be seen that the entire optical stack consists of a continuous optical medium with a uniform, regular oscillation with period λ/2 of refractive index down through the stack. The result is that the entire optical stack 119 comprised by device 100 is a photonic crystal with a stop-band centered on a wavelength λ.

The emitter layer 109 of device 100 contains an electroluminescent material whose emission spectrum overlaps the short wavelength band-edge of the stop band of photonic crystal 119. The result is that when the device is electrically activated by applying a voltage across the electrodes 105 and 113 there is an intense emission of light in a narrow wavelength band overlapping the band-edge. A large enough portion of this light is retained in photonic crystal 119 for a period of time long enough that it interacts with excitons formed in the emitter layer to induce stimulated emission in a vertical direction through stack 119 and out its top and bottom.

Another version of a BE-OLED of US patent is the same as device 100 except that the total optical thickness of central low refractive index zone 112 plus metal layer 106 equals 3λ/4 rather than λ/4. This device also functions as a photonic crystal in that the stack 119 for this device also induces a stop-band for light propagation in the vertical direction. Modeling has now disclosed that the optical thickness of central low refractive index zone 112 plus metal layer 106 may assume optical thickness values of (2n+1)λ/4 for n=0 to 3 with the resulting layer stacks like 119 still functioning as photonic crystals in that they induce stop-bands for light propagation in the vertical direction and stimulated emission of light is induced at the band edges of the stop-band.

As described in U.S. Pat. No. 11,139,456 and US Patent Application 2020/295,305 BE-OLEDs are fabricated by sequential vacuum deposition of a series of layers of different materials on a device substrate. Since twenty or more vacuum deposited layers may need to be built up, a drawback of BE-OLEDs is the expense of their production due to reduced fabrication yields and longer residence times in the vacuum deposition equipment. In addition, the versions of BE-OLEDs fabricated thus far require the fabrication of cathodes directly on top of the organic materials comprised by the electrically active portion of the devices. This most often requires sputtering of transparent electrode materials like indium-tin oxide on the organic layers and often results in sputter damage to the organic materials and device failure.

What is needed is a simpler BE-OLED configuration that requires the vacuum deposition of fewer layers and eliminates the potential for sputter damage to the organic layers of the device.

### BRIEF DESCRIPTION OF THE DRAWINGS

FIG. 1 illustrates a prior art BE-OLED, according to one embodiment.

FIG. 2 illustrates an improved BE-OLED, according to one embodiment.

### DETAILED DESCRIPTION

### Overview

Embodiments include a light emitting device. The light emitting device includes a single light emitting photonic crystal having a stop band and having organic electroluminescent emitter material disposed within the single photonic crystal. The light emitting device further includes a reflective metal cathode, the organic electroluminescent emitter material includes an organic light emitting material localized in a layer having less than 20% of an optical thickness of the photonic crystal, and the organic electroluminescent emitter material has a free space emission spectrum that at least in part overlaps the stop band of the photonic crystal. The photonic crystal emits light at a wavelength corresponding to an edge of the stop band, the photonic crystal has a periodically varying refractive index, the photonic crystal further includes alternating layers of high index of refraction materials and low index of refraction materials, one of the layers of low index of refraction materials includes a zone containing the organic electroluminescent emitter material, the zone including the organic electroluminescent emitter material further includes one or more additional sub-layers of organic materials each having a low index of refraction respective to an adjacent layer, wherein the additional organic materials are at least one of: (i) a charge transport material, (ii) a charge injection material, or (iii) a charge carrier blocking material, and the zone including the organic electroluminescent emitter material is adjacent to the reflective metal cathode.

Embodiments further include a light emitting device according to any of the embodiments described above, where the edge of the stop band occurs at a wavelength at which measured radiance of luminescence light emitted by the organic electroluminescent emitter material is greater than one-quarter of a peak radiance of a luminescence emission spectrum of the emitter material.

Embodiments further include a light emitting device according to any of the embodiments described above, where the edge of the stop band occurs at a wavelength at which light absorption for a single pass of light through an emitter layer is less than ½%.

Embodiments further include a light emitting device. The light emitting device includes a single light emitting photonic crystal having a stop band and having organic electroluminescent emitter material disposed within the single photonic crystal. The organic electroluminescent emitter material includes an organic light emitting material localized in a layer having less than 20% of an optical thickness of the photonic crystal, the organic electroluminescent emitter material has a free space emission spectrum that at least in part overlaps the stop band of the photonic crystal, and the photonic crystal emits light at a wavelength corresponding to an edge of the stop band. The photonic crystal has a periodically varying refractive index, the photonic crystal further includes alternating layers of high index of refraction materials and low index of refraction materials, one of the layers of low index of refraction materials includes a zone containing the organic electroluminescent emitter material, the zone including the organic electroluminescent emitter material further includes one or more additional sub-layers of organic materials each having a low index of refraction respective to an adjacent layer, wherein the additional organic materials are at least one of: (i) a charge transport material, (ii) a charge injection material, or (iii) a charge carrier blocking material, and the zone including the organic electroluminescent emitter material includes two materials that are capable of interacting to form a light emitting exciplex.

Embodiments further include a light emitting device according to any of the embodiments described above, where the light emitting device further includes a reflective metal cathode.

Embodiments further include a light emitting device according to any of the embodiments described above, where the zone including electroluminescent emitter material is adjacent to the reflective metal cathode.

Embodiments further include a light emitting device according to any of the embodiments described above, where the two materials that are capable of interacting to form a light emitting exciplex are 4,4′,4″tris(carbazole-9-yl)triphenylamine (TCTA) and 4,6-bis(3,5-di(pyridine-3-yl)phenyl)-2-methylpyrimidine (B3PyMPM).

Embodiments further include a light emitting device according to any of the embodiments described above, where the two materials that are capable of interacting to form a light emitting exciplex are 4,4′,4″tris(carbazole-9-yl)triphenylamine (TCTA) and 4,6-bis(3,5-di(pyridine-4-yl)phenyl)-2-methylpyrimidine (B4PyMPM).

### Example Embodiments

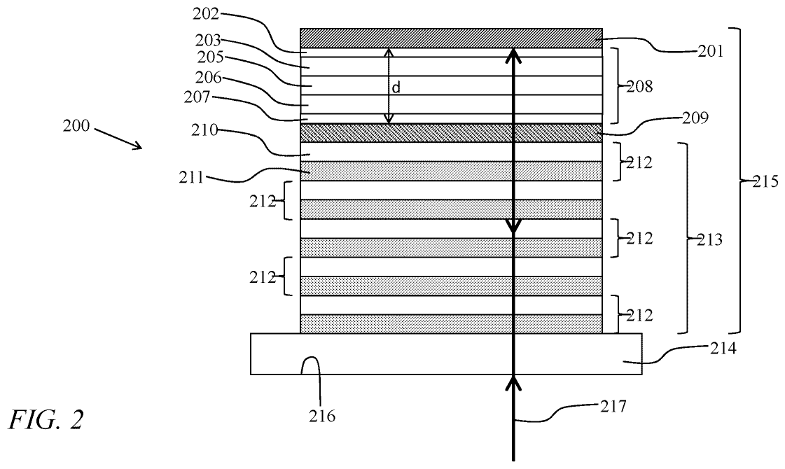

FIG. 2 portrays a new version 200 of BE-OLED generically described by U.S. Pat. No. 11,139,456 that has simplified, easier to manufacture structure. The device 200 comprises three sub-structures, a first portion 213 of the photonic crystal structure 215, a central low refractive index zone 208, and a cathode/reflector 201. These structures are successively built up on substrate 214 by vacuum deposition. The references to “a portion” are meant as convention to ease the description of the components of device 200 which is formed to be a single unitary one-dimensional photonic crystal 215. Aside from the three sub-structures listed above device 200 also comprises a transparent anode layer 209. Transparent anode 209 is formed from materials with higher refractive indices than adjacent low refractive index layers 210 and 207. Transparent anode layer 209 has an optical thickness equal to one-quarter of the central wavelength λ of the stop-band of the photonic crystal device 200.

The first portion 213 of the photonic crystal structure 215 comprises five layer pairs 212. Each of the layer pairs 212 comprises a layer 211 of transparent high refractive index material overlaid by a layer 210 of low refractive index material. Each of the layers comprised by layer pairs 212 may have an optical thickness equal to one-quarter of the central wavelength of the stop band of the photonic crystal 215. The optical thicknesses of the layers are equal to the physical thickness of the layers times the refractive index of the layer.

The central low refractive index zone 208 may comprise a hole injection layer 207, a hole transporting layer 206, an emitter layer 205, an electron transporting layer 203, and an electron injection layer 202. All of the layers contained in central low refractive index zone 208 have refractive indices lower than the material in anode 209. The combined optical thicknesses of the layers in zone 208 is equal to one-quarter of the central wavelength of the stop-band of the photonic crystal 215 and thus zone 208 acts optically as a single layer in the photonic crystal. The emitter layer in which all the photoluminescent material is localized has a thickness that is less than 20% of the total thickness of the photonic crystal structure 215.

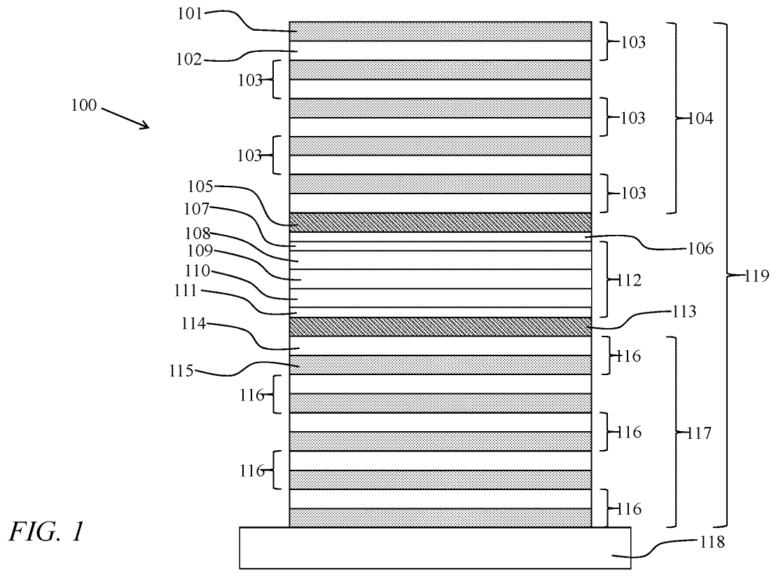

A cursory examination of FIG. 2 would seem to indicate that layer stack 215 would not function as well as a photonic crystal as layer stack 119 in device 100. This can be explained by examining the path of a light ray 217 at a wavelength outside of the stop band that enters device 200 through the bottom surface 216 of transparent substrate 214. The light then traverses the transparent substrate 214, the five layer pairs 212 of the first portion 213 of the photonic crystal structure 215 and then transparent anode 209 which acts as a high refractive index layer. Next the light ray traverses the central low refractive index zone 208, is reflected from reflective metal cathode/reflector 201 and then traverses central low refractive index zone 208 in the reverse direction. The ray then retraces its path back out of the device 200 through surface 216. What the light ray “sees” along this path is a structure equivalent to device structure 100 in FIG. 1, but with one exception. Its distance of travel through the optical medium of the central low refractive index zone 208 is twice the thickness d of zone 208.

Given the above analysis and also knowing that the optimum central layer thicknesses for devices with structure 100 is (2n+1)λ/4 we deduce that optimum values for the thickness of central low refractive index zone 208 is given by

$$d = ( 2 n + 1 ) λ / 8$$

where it is preferred that n=1 or 2.

It is preferred that the emitter layer 205 contains an emitter material whose free space electroluminescence emission yields a significantly high radiance at the band-edge wavelengths, that is to say, a radiance that when measured normal to the device surface is preferably at least 25% and most preferably at least 50% of the radiance at the peak spectral electroluminescence for the material. In other words, the measured radiance of luminescence light emitted by the light emitting material utilized in the organic light emitting diode is greater than one-quarter of the peak radiance of the luminescence emission spectrum of the emitter material measured normal to its light emitting surface. In other words, the emitter material in free space emits a substantial amount of light in the wavelengths corresponding to the band-edge wavelengths of the photonic crystal. For the sake of simplicity this is referred to as the emitter material emits light at the stop band wavelengths, or in the band-edge modes of the photonic crystal.

Preferably, to achieve a high efficiency BE-OLED device avoiding loses due to absorption of light in the emitter layer, the photonic crystal is configured such that an edge of the stop band falls at a wavelength between the peak emission wavelength of the electroluminescent material in the emitter layer and the wavelength at which the light emission intensity of the electroluminescent material is ¼ peak emission wavelength, in a region of the spectrum that overlaps areas of the absorption spectrum of the electroluminescent material as little as possible. In other words, in a spectral region where there is low absorption by the emitter material. Most preferably the photonic crystal is configured such that an edge of the band-gap falls between the peak electroluminescent emission wavelength and the ½ peak emission wavelength, in a region of the spectrum that overlaps areas of the absorption spectrum as little as possible, in other words, in a region where there is low absorption by the electroluminescent emitter material. The band-gap edge may fall at a wavelength at which light absorption for a single pass of light through the emitter layer is less than 1%. Preferably, the band edge may fall on a wavelength at which light absorption for a single pass or light through the emitter layer is less than ½%, while also corresponding to a wavelength of the emission spectrum that is greater than 14 of the peak radiance.

Self-absorption by the electroluminescent emitter material is an important issue that that may limit the energy efficiency of BE-OLEDs. A way to eliminate self-absorption in BE-OLEDs is to utilize an exciplex as the electroluminescent emissive species. An exciplex is formed when a material in the emitter layer is electrically energized into an excited state forming an exciton. Instead of immediately emitting light the highest energy occupied molecular orbital of the excited state molecule overlaps the lowest energy unoccupied molecular orbital of a neighboring molecule of a second material forming a short-lived complex species, the exciplex. The excited state electron of the first material now occupies a molecular orbital of the exciplex that is at a lower energy level than that that the electron occupied in the excited state of the first material. Because light emission is now from the lower energy, exciplex molecular orbital its light emission is red-shifted spectrally. The result is that light emission from the exciplex is at wavelengths that are spectrally well way from the spectral light absorption bands of the two materials that form the exciplex and self-absorption from the exciplex materials is negligible. In addition, another advantage is that the exciplex light emission bands are spectrally broad and as a result, the band-edge of a photonic crystal stop band can be designed to overlap a much wider band of wavelengths of light than is possible with most individual emitters. That is to say, the light emission wavelength of a BE-OLED utilizing an exciplex emitter can be tuned over a wider range of wavelengths than is the case with many single molecule light emitting materials.

Examples of exciplex emitter material combinations useful in BE-OLEDs are:
1. A mixture of 4,4′,4″tris(carbazole-9-yl)triphenylamine (TCTA) with 4,6-bis(3,5-di(pyridine-3-yl)phenyl)-2-methylpyrimidine (B3PyMPM) that yields an exciplex that emits at approximately 495 nm.
2. A mixture of 4,4′,4″tris(carbazole-9-yl)triphenylamine (TCTA) with 4,6-bis(3,5-di(pyridine-4-yl)phenyl)-2-methylpyrimidine (B4PyMPM) that yields an exciplex that emits at approximately 525 nm.
3. A mixture of 1,3-bis(N-carbazoyl)benzene (mCP) with 2,4,6-tris[3-(diphenylphosphinyl)phenyl]-1,3,5-triazine (PO-T2T) that yields an exciplex that emits at 470 nm.
4. A mixture of 4,4′,4″-tris[phenyl(m-tolyl)amino]triphenylamine (m-MTDATA) with 2-((2,2′:6′,2″-terpyridin)-4′-yl)9H-thioxanthen-9-one (Tx-TerPy) that yields an exciplex that emits at 590 nm.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

While the foregoing is directed to embodiments of the present invention, other and further embodiments of the invention may be devised without departing from the basic scope thereof, and the scope thereof is determined by the claims that follow.

1. A light emitting device, comprising:
a single light emitting photonic crystal having a stop band and having organic electroluminescent emitter material disposed within the single photonic crystal,
wherein the light emitting device further comprises a reflective metal cathode,
wherein the organic electroluminescent emitter material comprises an organic light emitting material localized in a layer having less than 20% of an optical thickness of the photonic crystal,
further wherein the organic electroluminescent emitter material has a free space emission spectrum that at least in part overlaps the stop band of the photonic crystal,
further wherein the photonic crystal emits light at a wavelength corresponding to an edge of the stop band,
further wherein the photonic crystal has a periodically varying refractive index,
further wherein the photonic crystal further comprises alternating layers of high index of refraction materials and low index of refraction materials,
further wherein one of the layers of low index of refraction materials comprises a zone containing the organic electroluminescent emitter material,
further wherein the zone comprising the organic electroluminescent emitter material further comprises one or more additional sub-layers of organic materials each having a low index of refraction respective to an adjacent layer, wherein the additional organic materials are at least one of: (i) a charge transport material, (ii) a charge injection material, or (iii) a charge carrier blocking material, and
further wherein the zone comprising the organic electroluminescent emitter material is adjacent to the reflective metal cathode.

2. The light emitting device of claim 1, wherein the edge of the stop band occurs at a wavelength at which measured radiance of luminescence light emitted by the organic electroluminescent emitter material is greater than one-quarter of a peak radiance of a luminescence emission spectrum of the emitter material.

3. The light emitting device of claim 1, wherein the edge of the stop band occurs at a wavelength at which light absorption for a single pass of light through an emitter layer is less than ½%.

4. A light emitting device, comprising:
a single light emitting photonic crystal having a stop band and having organic electroluminescent emitter material disposed within the single photonic crystal,
wherein the organic electroluminescent emitter material comprises an organic light emitting material localized in a layer having less than 20% of an optical thickness of the photonic crystal,
further wherein the organic electroluminescent emitter material has a free space emission spectrum that at least in part overlaps the stop band of the photonic crystal,
further wherein the photonic crystal emits light at a wavelength corresponding to an edge of the stop band,
further wherein the photonic crystal has a periodically varying refractive index,
further wherein the photonic crystal further comprises alternating layers of high index of refraction materials and low index of refraction materials,
further wherein one of the layers of low index of refraction materials comprises a zone containing the organic electroluminescent emitter material,
further wherein the zone comprising the organic electroluminescent emitter material further comprises one or more additional sub-layers of organic materials each having a low index of refraction respective to an adjacent layer, wherein the additional organic materials are at least one of: (i) a charge transport material, (ii) a charge injection material, or (iii) a charge carrier blocking material, and
further wherein the zone comprising the organic electroluminescent emitter material comprises two materials that are capable of interacting to form a light emitting exciplex.

5. The light emitting device of claim 4 wherein the light emitting device further comprises a reflective metal cathode.

6. The light emitting device of claim 5 wherein the zone comprising electroluminescent emitter material is adjacent to the reflective metal cathode.

7. The light emitting device of claim 4 wherein the two materials that are capable of interacting to form a light emitting exciplex are 4,4′,4″tris(carbazole-9-yl)triphenylamine (TCTA) and 4,6-bis(3,5-di(pyridine-3-yl)phenyl)-2-methylpyrimidine (B3PyMPM).

8. The light emitting device of claim 4 wherein the two materials that are capable of interacting to form a light emitting exciplex are 4,4′,4″tris(carbazole-9-yl)triphenylamine (TCTA) and 4,6-bis(3,5-di(pyridine-4-yl)pheny1)-2-methylpyrimidine (B4PyMPM).
